(19) United States
(12) Patent Application Publication
(10) Pub. No.: US 2025/0240889 A1
(43) Pub. Date: Jul. 24, 2025

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Ra-Min Tain, Hsinchu County (TW); Cheng-Ta Ko, Taipei City (TW); Guang-Hwa Ma, Hsinchu City (TW)

(73) Assignee: Unimicron Technology Corp., Taoyuan City (TW)

(21) Appl. No.: 19/023,397

(22) Filed: Jan. 16, 2025

Related U.S. Application Data
(63) Continuation-in-part of application No. 18/677,924, filed on May 30, 2024.
(60) Provisional application No. 63/623,823, filed on Jan. 23, 2024.
(60) Provisional application No. 63/666,227, filed on Jun. 30, 2024.

(30) Foreign Application Priority Data
Apr. 30, 2024 (TW) 113116076
Nov. 14, 2024 (TW) 113143769

(51) Int. Cl. H05K 1/14; H05K 1/11; H05K 3/46

(52) U.S. Cl. CPC H05K 1/144; H05K 1/115; H05K 3/4638; H05K 2201/041

(57) ABSTRACT

A substrate structure including a first substrate and a second substrate is provided. The first substrate includes a first core layer and a first conductor. The second substrate includes a second core layer and a second conductor. There is a metal diffusion bonding interface between the first conductor and the second conductor. There is a covalent bonding interface between the first core layer and the second core layer.

### CROSS-REFERENCE TO RELATED APPLICATION

This application is a continuation-in-part application of and claims the priority benefit of U.S. application Ser. No. 18/677,924, filed on May 30, 2024, now pending. The prior U.S. application Ser. No. 18/677,924 claims the priority benefits of U.S. provisional application Ser. No. 63/623,823, filed on Jan. 23, 2024, and Taiwan application serial no. 113116076, filed on Apr. 30, 2024. This application also claims the priority benefit of U.S. provisional application Ser. No. 63/666,227, filed on Jun. 30, 2024, and Taiwan application serial no. 113143769, filed on Nov. 14, 2024. The entirety of each of the above-mentioned patent applications is hereby incorporated by reference herein and made a part of this specification.

### BACKGROUND

### Technical Field

The disclosure relates to a substrate structure and a manufacturing method thereof, and in particular relates to a substrate structure having a conductive via and a manufacturing method thereof.

### Description of Related Art

At present, to create high aspect ratio (AR) through glass vias (TGVs) in glass substrates, glass substrates are bonded together through resin material. Subsequently, the through glass vias in two glass substrates are electrically connected through the conductive paste in the resin material. That is, after the two glass substrates are bonded, there is conductive paste between the through glass vias. Alternatively, the thickness of the glass substrate adopted is greater than 200 microns, such as 500 microns, and high aspect ratio through glass vias are formed through laser, etching, hole filling and other processes. It may be seen that it is difficult to produce high aspect ratio through glass vias in glass substrates.

### SUMMARY

A substrate structure and a manufacturing method thereof are provided in the disclosure, in which the included substrate structure and the manufacturing method thereof may have high aspect ratio through glass vias.

A manufacturing method of a substrate structure of the disclosure includes the following operation. A first substrate including a first core layer and a first conductor that is exposed is provided. A second substrate including a second core layer and a second conductor that is exposed is provided. Conductive nano-wires are formed on the first conductor or the second conductor. The first conductor of the first substrate is aligned with the second conductor of the second substrate, and the conductive nano-wires are located between the first conductor and the second conductor, so that the first substrate and the second substrate are bonded by at least conductive diffusion bonding formed by the conductive nano-wires.

In one embodiment, the first conductor or the second conductor includes the same material as the conductive nano-wires.

In one embodiment, the first conductor or the second conductor includes a copper layer, and the conductive nano-wires are copper nano-wires.

In one embodiment, the copper nano-wires are directly formed on the copper layer.

In one embodiment, the first substrate or the second substrate further includes a polymer, and during the aligning the first conductor of the first substrate with the second conductor of the second substrate, the polymer is further located between the first core layer and the second core layer, so that the first substrate and the second substrate are further bonded through a chain or network structure formed by the polymer.

In one embodiment, during the bonding the first substrate and the second substrate that are separated from each other, the temperature is less than or equal to 200° C.

In one embodiment, the polymer includes a silicone polymer, and the chain or network structure has at least bridging oxygen.

A substrate structure of the disclosure includes a first substrate and a second substrate. The first substrate includes a first core layer and a first conductor. The second substrate includes a second core layer and a second conductor. There is a metal diffusion bonding interface between the first conductor and the second conductor. There is a covalent bonding interface between the first core layer and the second core layer.

In one embodiment, the metal diffusion bonding interface is a copper diffusion bonding interface.

In one embodiment, the covalent bonding interface is a chain or network structure having at least bridging oxygen.

Based on the above, because conductive nano-wires have the characteristics of low melting point and high surface area, the temperature in the manufacturing process operation may be reduced, and problems such as warping and cracking of the chip in an element caused by excessive temperature during the bonding process may be avoided. Therefore, having copper bonding between conductive nano-wires allows for lower heating temperatures to improve the quality of through glass vias with high aspect ratios.

### BRIEF DESCRIPTION OF THE DRAWINGS

FIG. 1 to FIG. 12 are partial cross-sectional schematic diagrams of a partial manufacturing method of a substrate structure according to the first embodiment of the disclosure.

FIG. 13 to FIG. 19 are partial cross-sectional schematic diagrams of a partial manufacturing method of a substrate structure according to the second embodiment of the disclosure.

### DETAILED DESCRIPTION OF DISCLOSED EMBODIMENTS

The following examples are described in detail with the accompanying drawings, but the provided examples are not intended to limit the scope of the disclosure. In addition, the drawings are for illustrative purposes only and are not drawn in full scale.

In addition, the terms such as “including”, “having”, etc. used in the text are all open- ended terms, that is, “including but not limited to”.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion. Thus, “a first element,” “component,” “region,” “layer,” or “portion” discussed below may be referred to as a second element, component, region, layer, or portion without departing from the teachings herein.

In the disclosure, wordings used to indicate directions, such as “up,” “down,” “top,” and “bottom,” merely refer to directions in the accompanying drawings. Therefore, the directional terms are used to illustrate rather than limit the disclosure.

In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

In the following embodiments, the same or similar elements will be designated by the same or similar reference numerals, and descriptions thereof will be omitted. In addition, the features of different embodiments may be combined with each other when they are not in conflict, and simple equivalent changes and modifications made according to the specification or the claims are still within the scope of the disclosure.

### First Embodiment

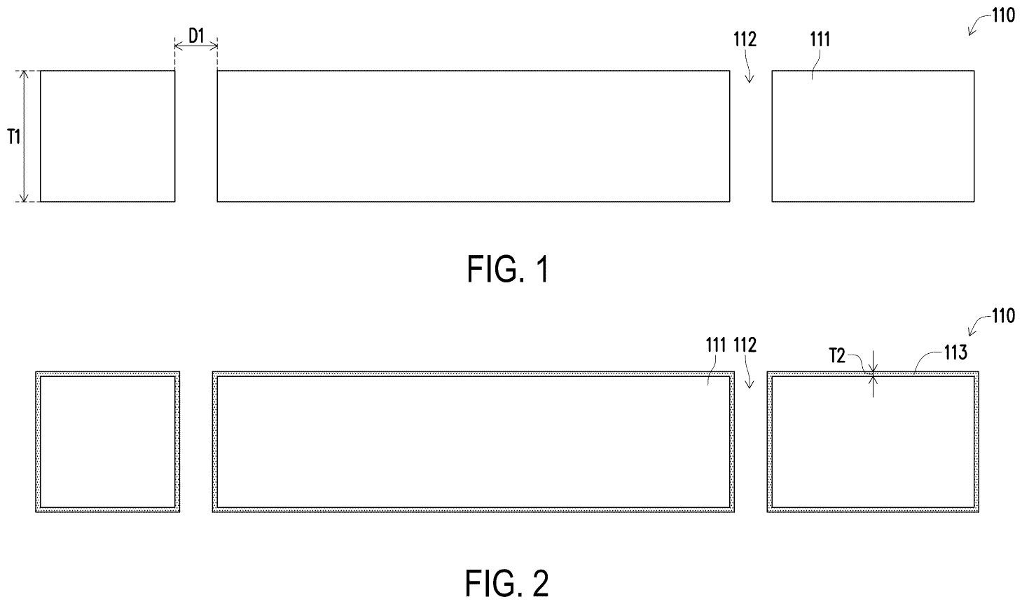

FIG. 1 to FIG. 12 are partial cross-sectional schematic diagrams of a partial manufacturing method of a substrate structure according to the first embodiment of the disclosure. FIG. 1 to FIG. 5 are partial cross-sectional schematic diagrams of forming the first substrate 110 with conductive vias.

Referring to FIG. 1, a first substrate 110 is provided. The first substrate 110 includes a core substrate 111 and at least one via 112 (two vias are schematically shown) penetrating the core substrate 111.

In one embodiment, the core substrate 111 may be a glass substrate. In one embodiment, the core substrate 111 may also be a ceramic substrate, a bismaleimide triazine (BT) substrate, an epoxy glass fiber unclad laminate (e.g., FR4) substrate, a polyimide (PI) substrate, an Ajinomoto build-up film (ABF) substrate or a multi-layer circuit board, but the disclosure is not limited thereto. In one embodiment, the thickness T1 of the core substrate 111 may be in a range between about 100 microns and about 400 microns.

In one embodiment, the via 112 may be a penetrating via. In one embodiment, the via 112 may be formed by mechanical drilling, laser drilling, etching, or other suitable methods. In one embodiment, the via 112 may be a through glass via, in which the diameter D1 of the via 112 may be in a range between about 20 microns and about 150 microns.

Referring to FIG. 2, an insulating layer 113 may be selectively formed on the core substrate 111 and on the sidewalls of the via 112. In one embodiment, the insulating layer 113 may include an adhesion promotion layer (APL). The insulating layer may be formed, for example, by deposition or other suitable methods. In one embodiment, the insulating layer 113 includes an oxide, a nitride, a combination thereof, such as silicon dioxide (e.g., SiO₂ or SiOₓ), aluminum oxide (e.g., Al₂O₃), titanium oxide (e.g., TiO₂ or TiO or TiOₓ) or silicon nitride (Si₃N₄ or SiNₓ), but the disclosure is not limited thereto. In one embodiment, the thickness T2 of the insulating layer 113 may be in a range between about 0.01 nanometers and about 100 nanometers.

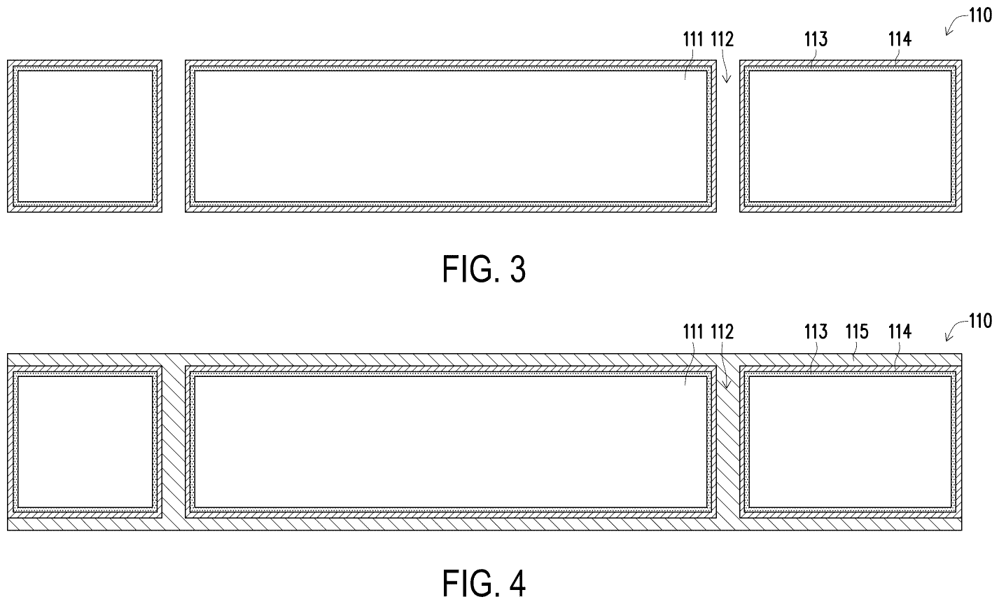

Referring to FIG. 3, a first conductive layer 114 may be selectively formed on the core substrate 111 and on the sidewalls of the via 112. The first conductive layer 114 may cover the insulating layer 113 (if present).

In one embodiment, the first conductive layer 114 may be referred to as a seed layer. In one embodiment, the first conductive layer 114 may include copper or/and titanium, but the disclosure is not limited thereto. In one embodiment, the first conductive layer 114 may be formed by using a sputtering process or an electroless plating process, or a sputtering process may be used first and then an electroless plating process may be used to completely cover the sidewalls of the via 112.

Referring to FIG. 4, a second conductive layer 115 is formed at least within the via 112. The second conductive layer 115 may be formed on the first conductive layer 114 (if present). In one embodiment, the second conductive layer 115 may be a copper layer. In one embodiment, the second conductive layer 115 may be formed by electroplating.

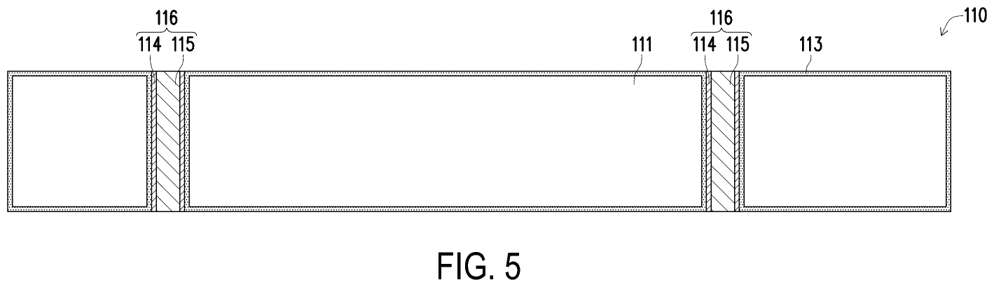

Referring to FIG. 5, a portion of the first conductive layer 114 and a portion of the second conductive layer 115 outside the via 112 are removed. The first conductive layer 114 and the second conductive layer 115 in the via 112 may be retained to form the conductive via 116. That is, the conductive via 116 includes the first conductive layer 114 and the second conductive layer 115, and the conductive via 116 penetrates the core substrate 111. That is, in FIG. 5, multiple conductive vias 116 may be electrically separated from each other.

It is worth noting that FIG. 5 or other similar figures may only illustrate a portion of an embodiment or a cross-section of a portion of an embodiment. In an unillustrated embodiment or an unillustrated cross-section, a portion of the first conductive layer 114 and a portion of the second conductive layer 115 may be retained on the upper surface (towards to the top of the diagram) or lower surface (towards to the bottom of the diagram) of the core substrate 111. These retained portions of the first conductive layer 114 and the second conductive layer 115 may have alignment patterns, which may form appropriate wires (e.g., may be referred to as a wiring layer) or marks (e.g., may be referred to as position marks).

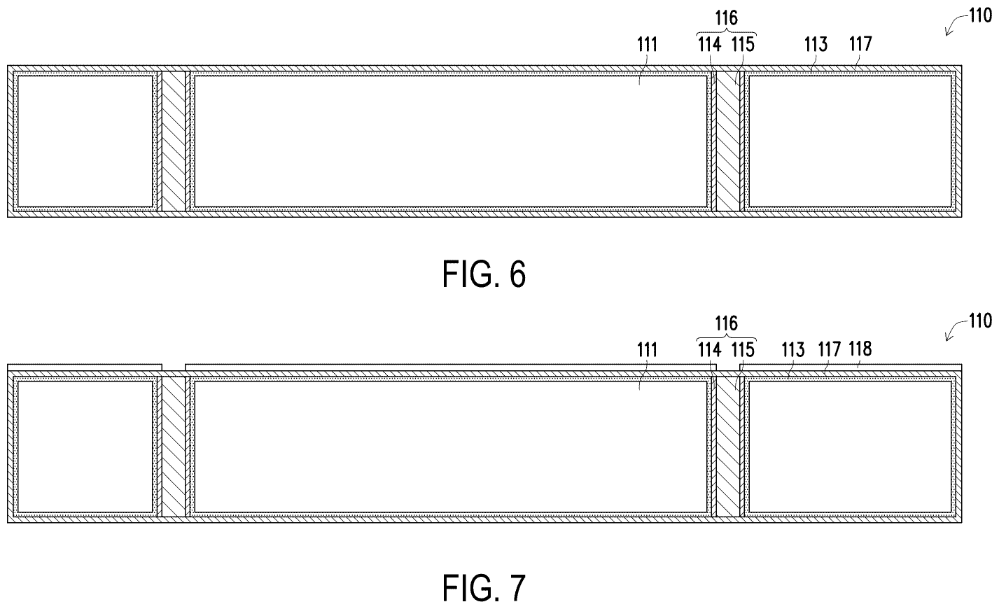

FIG. 6 to FIG. 9 are partial cross-sectional schematic diagrams of forming conductive nano-wires 120 on the conductive via 116.

Referring to FIG. 6, a third conductive layer 117 may be selectively formed on at least one side of the first substrate 110.

In one embodiment, the third conductive layer 117 may be referred to as a seed layer. In one embodiment, the third conductive layer 117 may include copper or/and titanium, but the disclosure is not limited thereto. In one embodiment, the third conductive layer 117 may be formed by using a sputtering process or an electroless plating process, or a sputtering process may be used first and then an electroless plating process may be used so that the sidewalls of the conductive via 116 may be completely covered.

In an embodiment, the third conductive layer 117 may be referred to as a conductive connection layer. That is, the conductive vias 116 that are electrically separated from each other in FIG. 5 may be electrically connected through the third conductive layer 117 in FIG. 6.

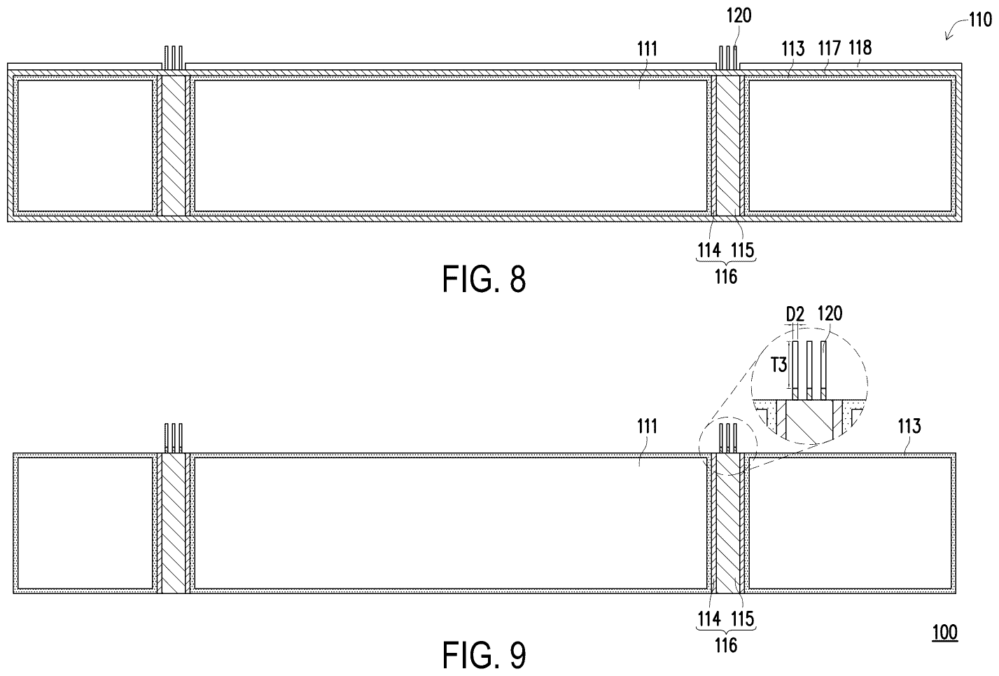

Referring to FIG. 7, a patterned mask layer 118 is formed on at least one side of the core substrate 111. The openings in the patterned mask layer 118 may expose a portion of the third conductive layer 117. The openings of the patterned mask layer 118 may align with positions where conductive nano-wires (e.g., conductive nano-wires 120 as shown in FIG. 8) are to be formed.

The material of the patterned mask layer 118 is different from the material of the third conductive layer 117, and its purpose is to make it easier for subsequent conductive nano-wires (the conductive nano-wires 120 shown in FIG. 8) to be located on the exposed portion of the third conductive layer 117 and to be less easily located on the patterned mask layer 118. For example, subsequent conductive nano-wires may be formed more easily on the exposed portion of the third conductive layer 117 but less easily formed on the patterned mask layer 118. For another example, even though subsequent conductive nano-wires may be formed on the third conductive layer 117 and the patterned mask layer 118, the conductive nano-wires on the patterned mask layer 118 may be easily removed (e.g., through peeling). In one embodiment, the material of the patterned mask layer 118 may include photoresist. In one embodiment, the photoresist layer 118 may include a dry film.

Referring to FIG. 8, conductive nano-wires 120 are formed. The material of the conductive nano-wires 120 is substantially the same or similar to the material of the third conductive layer 117. For example, the third conductive layer 117 is a copper layer, and the conductive nano-wires 120 are copper nano-wires. For another example, the third conductive layer 117 is a copper layer, the conductive nano-wires 120 are copper nano-wires, and the concentration or lattice state of copper in the third conductive layer 117 is substantially the same or similar to the concentration or lattice state of copper in the conductive nano-wires 120.

In one embodiment, a porous film layer (not marked) may be heat-pressed on the portion of the third conductive layer 117 exposed by the patterned mask layer 118. The aforementioned porous film layer may form a growth template for the conductive nano-wires 120. Then, conductive nano-wires 120 for alignment are formed on the growth template by an appropriate method (e.g., copper electroplating).

In one embodiment, the thickness of the conductive nano-wires 120 (i.e., the alignment height of a majority of each conductive nano-wire 120 for alignment; or, its average) is greater than the thickness of the third conductive layer 117. In this way, it may be suitable for subsequent manufacturing processes. In one embodiment, the thickness of the conductive nano-wire 120 may be adjusted by appropriate means (e.g., the concentration of metal ions in the plating solution, the current of electroplating, the formation time or temperature, etc.).

In the aspect shown in FIG. 8, the height of the conductive nano-wire 120 is higher than the patterned mask layer 118, but the disclosure is not limited thereto. That is, the height of the conductive nano-wire 120 may be lower than the patterned mask layer 118, and the aspect shown in FIG. 8 is only an exaggerated illustration to emphasize the conductive nano-wires 120.

Referring to FIG. 8 to FIG. 9, an appropriate removal process (which may include one or more removal steps and cleaning steps) may be performed to remove at least the photoresist layer 118 (shown in FIG. 8) and a portion of the third conductive layer 117, to form the structure shown in FIG. 9.

In one embodiment, a portion of the third conductive layer 117 (e.g., a portion of the third conductive layer 117 under the conductive nano-wire 120) may be retained. In one embodiment, during the aforementioned removal process, some of the conductive nano-wires 120 may be removed (e.g., shorter or peripheral conductive nano-wires 120 may be removed); and/or, a portion of the conductive nano-wires 120 may be removed (e.g., a portion of the conductive nano-wires 120 may be removed to make the conductive nano-wires 120 shorter or thinner). That is, compared with the conductive nano-wires 120 in FIG. 8, the distribution of the conductive nano-wires 120 in FIG. 9 may be smaller, the conductive nano-wires 120 may have a reduced thickness, and/or the conductive nano-wires 120 may have a reduced width. That is, if the conductive nano-wire 120 in FIG. 8 has a first distribution range, and the conductive nano-wire 120 in FIG. 9 has a second distribution range, the second distribution range is smaller than the first distribution range. That is, if the conductive nano-wire 120 in FIG. 8 has a first thickness, and the conductive nano-wire 120 in FIG. 9 has a second thickness, the second thickness is thinner than the first thickness. That is, if the conductive nano-wire 120 in FIG. 8 has a first diameter, and the conductive nano-wire 120 in FIG. 9 has a second diameter, the second diameter is smaller than the first diameter. In addition, the aforementioned thickness or diameter may be an average value obtained through appropriate measurement methods (e.g., an electron microscope) of multiple conductive nano-wires 120. In addition, after the aforementioned removal process, the electrical and/or physical properties of the conductive nano-wires 120 will not change much (e.g., they are still basically electrically connected to the aligned conductive vias 116; and/or, the lattice state is basically the same), the same reference numeral (i.e., 120) is consistently used to mark these elements in FIG. 9 and subsequent figures.

From the enlarged view, the thickness T3 of the conductive nano-wires 120 may be in a range between about 1 micron and about 50 microns, and the line diameter or line width D2 of the conductive nano-wires 120 may be in a range between about 4 nanometers and about 4 microns.

In addition, before the aforementioned removal process is performed, the thickness of the conductive nano-wire 120 (i.e., the thickness of the conductive nano-wire 120 in FIG. 8) is already greater than the thickness of the third conductive layer 117. Therefore, the conductive nano-wire 120 may still be retained after appropriate processing (i.e., FIG. 9).

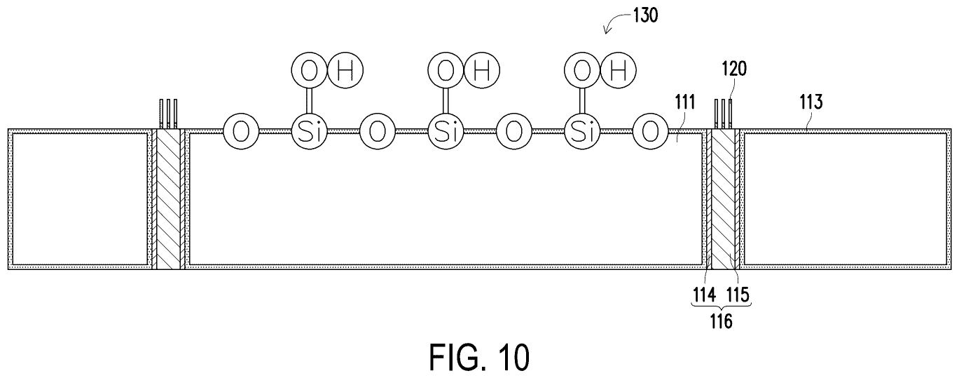

FIG. 10 to FIG. 12 are partial cross-sectional schematic diagrams of the bonding two substrates 110 and 210 to form the substrate structure 100 of the first embodiment of the disclosure.

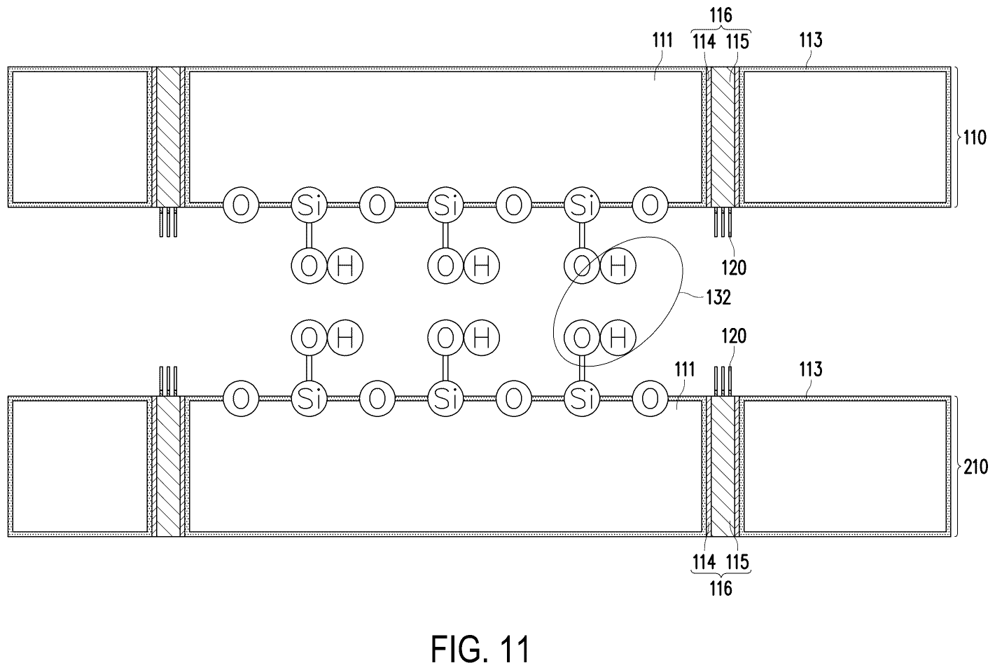

Referring to FIG. 10 and FIG. 11, a second substrate 210 that is the same as or similar to the first substrate 110 is provided, and the first substrate 110 and the second substrate 210 are chemically bonded.

In one embodiment, the core substrates 111 in the first substrate 110 and the second substrate 210 are bonded through a sol-gel process. The sol-gel process mainly goes through two stages: a hydrolysis reaction 130 and a condensation reaction 132.

In the hydrolysis reaction 130 stage, the starting reactant may be silane oxide (Si(OR)₄, where R is an alkyl functional group; for example, it includes: methyl, ethyl, propyl or isopropyl) (not marked and not limited thereto), which becomes hydroxide after hydrolysis. The chemical reaction formula may be as shown in the following <Reaction Formula 1>. In addition, FIG. 10 only schematically presents the molecular structural formula after the hydrolysis reaction 130, and therefore R is not marked.

Si—OR+H₂O→Si—OH+R—OH Reaction Formula 1

In one embodiment, a temperature exceeding 100 degrees Celsius may facilitate the hydrolysis reaction. For example, water molecules produced by hydrolysis reactions may easily become gases and be removed at temperatures exceeding 100 degrees Celsius.

In the condensation reaction 132 stage, after heating, the silane oxide containing hydroxyl groups easily reacts with the hydroxyl groups in other alkoxides to form covalent bonds, and after continuous reactions, polymerizes into a chain or network structure with bridging oxygen. The chemical reaction formula may be as shown in the following <Reaction Formula 2>.

Si—OH+HO—Si→Si—O—Si+H₂O <Reaction Formula 2>

In one embodiment, the core substrate 111 of the first substrate 110 and the core substrate 111 of the second substrate 210 are bonded through polymerization of macromolecules. In FIG. 11, the molecular structural formula during the condensation reaction 132 is only schematically presented.

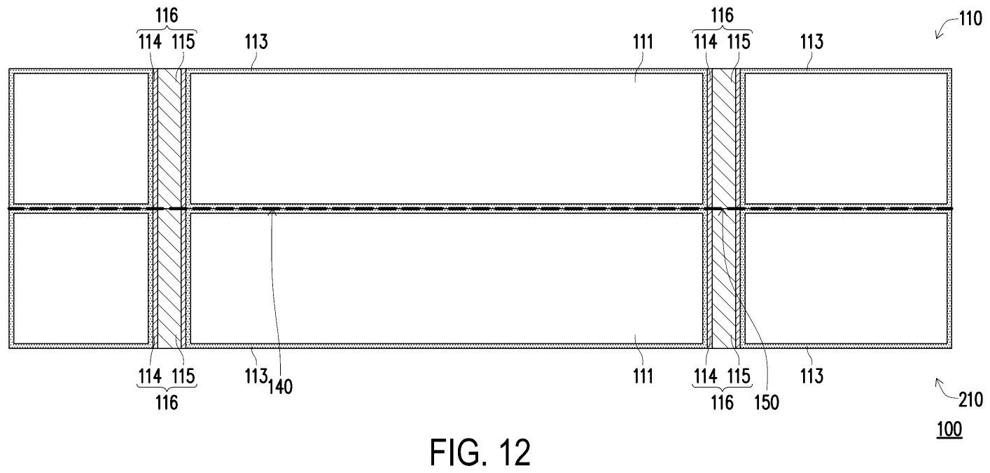

Referring to FIG. 12, the first substrate 110 and the second substrate 210 are bonded during heating, so that the core layer 111 of the first substrate 110 and the core layer 111 of the second substrate 210 are bonded through chemical bonding force (as described above). Furthermore, the conductive nano-wires 120 on the conductive via 116 of the first substrate 110 and the conductive nano-wires 120 on the conductive via 116 of the second substrate 210 are also heated to perform metal-to-metal diffusion bonding. Therefore, the core layer 111 and the conductive nano-wires 120 of the first substrate 110 are bonded to the core layer 111 and the conductive nano-wires 120 of the second substrate 210 to form the substrate structure 100 of the first embodiment.

In one embodiment, the conductive nano-wires 120 of the first substrate 110 and the conductive nano-wires 120 of the second substrate 210 are both copper nano-wires, and Cu-to-Cu diffusion bonding may be achieved between them through heating.

The conductive nano-wire 120 has the characteristics of low melting point and high surface area, so the temperature and pressure during the manufacturing process operation may be reduced, thereby reducing or even avoiding problems such as warping and cracking of the chip in an element caused by excessive temperature and pressure during the bonding process. Taking copper nano-wires as an example, the copper bonding between them may allow for lower heating temperatures (i.e., lower than the melting point of metallic copper), such as no more than about 200 degrees Celsius. In one embodiment, the heating temperature may be in a range between about 100 degrees Celsius and about 200 degrees Celsius, such as about 170 degrees Celsius (170° C.).

Please continue to refer to FIG. 12, the substrate structure 100 of the first embodiment of the disclosure includes a first substrate 110 and a second substrate 210. In one embodiment, both the first substrate 110 and the second substrate 210 include a core layer 111 and a conductive via 116. In one embodiment, an insulating layer 113 may be selectively included on the core layer 111 and/or on the sidewalls of the conductive via 116. The conductive via 116 may include a first conductive layer 114 and a second conductive layer 115.

In one embodiment, there is a metal diffusion bonding interface 150 between the conductive via 116 of the first substrate 110 and the conductive via 116 of the second substrate 210. In one embodiment, the metal diffusion bonding interface 150 is a copper diffusion bonding interface. In one embodiment, the metal diffusion bonding interface 150 is formed by aligned metal nano-wires (a type of conductive nano-wires, such as copper nano-wires). In one embodiment, although the metal diffusion bonding interface 150 is described as a “bonding interface”, structurally, it may be a thin layer structure or a structure in which nano-wires are interwoven and bonded. In one embodiment, the material of the conductive via 116 is the same as or similar to the material of the metal diffusion bonding interface 150. In one embodiment, when the material of the conductive via 116 and the material of the metal diffusion bonding interface 150 are substantially the same, there may be no obvious interface or layering therebetween (e.g.: between the conductive via 116 of the first substrate 110 and the conductive via 116 of the second substrate 210; and/or, between a certain conductive via 116 and the metal diffusion bonding interface 150).

In one embodiment, there is a covalent bonding interface 140 between the core layer 111 of the first substrate 110 and the core layer 111 of the second substrate 210 through chemical bonding force. In one embodiment, although the covalent bonding interface 140 is described as a “bonding interface”, structurally it may be a thin layer structure.

### Second Embodiment

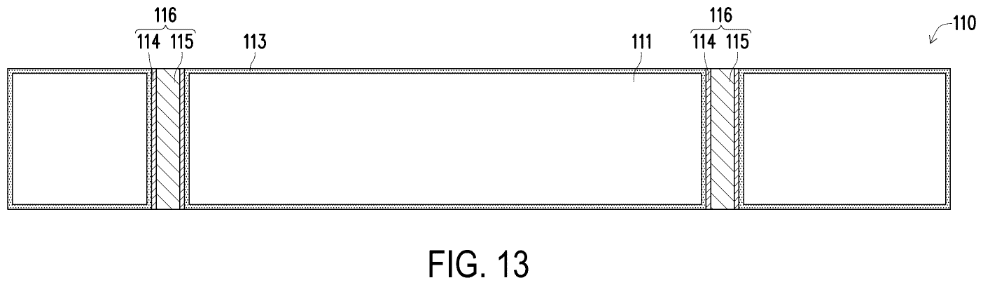

FIG. 13 to FIG. 19 are partial cross-sectional schematic diagrams of a partial manufacturing method of a substrate structure according to the second embodiment of the disclosure.

The structure and manufacturing method of the substrate structure 200 of the second embodiment of the disclosure are similar to the substrate structure 100 of the first embodiment. The only main difference between the two is that an organic resin layer 202 is included on the core layer 111 of at least one of the first substrate 110 and the second substrate 210.

FIG. 13 is a partial cross-sectional diagram of forming the first substrate 110 with conductive vias 116. FIG. 13 is the same as FIG. 5 of the first embodiment. The manufacturing method of the first substrate 110 with the conductive vias 116 is the same as or similar to FIG. 1 to FIG. 5 of the first embodiment.

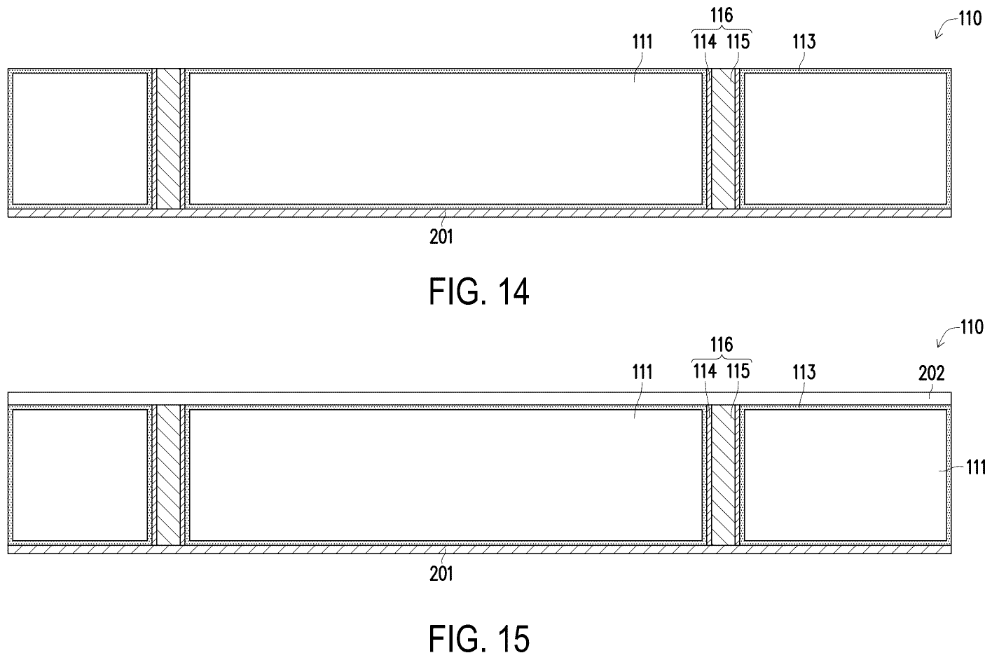

FIG. 14 to FIG. 18 are partial cross-sectional schematic diagrams of forming the organic resin layer 202 on the core layer 111 and forming the conductive nano-wires 120 on the conductive vias 116.

Referring to FIG. 14, in some embodiments, after forming the first substrate 110 with the conductive vias 116, a fourth conductive layer 201 may be formed on one side of the first substrate 110. In one embodiment, the fourth conductive layer 201 may function as a common electrode. In one embodiment, the conductive vias 116 that are electrically separated from each other in FIG. 13 may be electrically connected through the fourth conductive layer 201 in FIG. 15. In one embodiment, the fourth conductive layer 201 may include copper, but the disclosure is not limited thereto. In one embodiment, the fourth conductive layer 201 may be formed by using a sputtering process, but the disclosure is not limited thereto.

In one embodiment, the first substrate 110 and the second substrate 210 of the aforementioned first embodiment may also selectively include conductive layers that are the same as or similar to the fourth conductive layer 201.

Referring to FIG. 15, an organic resin layer 202 is formed on another side of the first substrate 110 opposite to the side including the fourth conductive layer 201. In one embodiment, the material of the organic resin layer 202 may include liquid-crystal polymer (LCP), but the disclosure is not limited thereto.

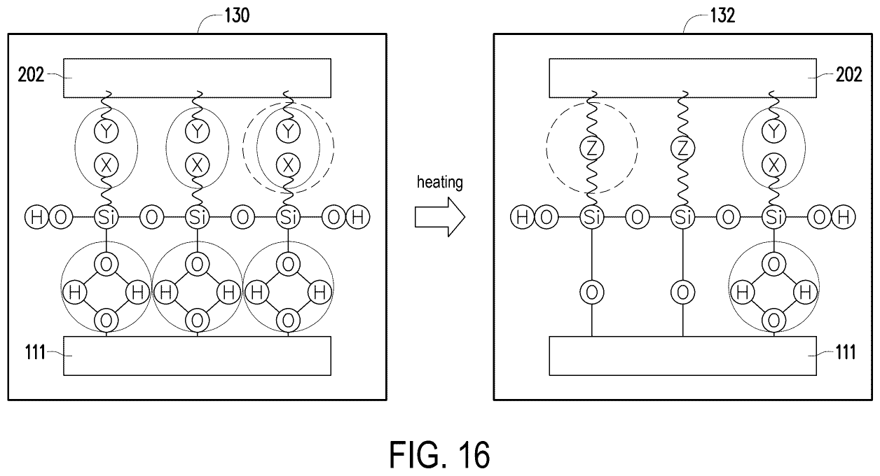

Referring to FIG. 16 to FIG. 18, a second substrate 210 that is the same as or similar to the first substrate 110 is provided, and the core substrates 111 in the first substrate 110 and the second substrate 210 are chemically bonded.

In one embodiment, the core substrates 111 in the first substrate 110 and the second substrate 210 are bonded through a sol-gel process. The sol-gel process mainly goes through two stages: a hydrolysis reaction 130 and a condensation reaction 132.

In the hydrolysis reaction 130 stage, the starting reactant may be silane oxide (Si(OR)₄), where R is an alkyl functional group in the organic resin layer 202, and becomes hydroxide after hydrolysis. The chemical reaction formula may be as shown in the aforementioned <Reaction Formula 1>. The molecular structural formula of the hydrolysis reaction 130 is only schematically presented in the left frame (130) of FIG. 16.

In the condensation reaction 132 stage, after heating, the silane oxide containing hydroxyl groups easily reacts with the hydroxyl groups in other alkoxides to form covalent bonds, and after continuous reactions, polymerizes into a chain or network structure with bridging oxygen. The chemical reaction formula may be as shown in the aforementioned <Reaction Formula 2>. The core substrate 111 of the first substrate 110 and the core substrate 111 of the second substrate 210 are bonded through polymerization of macromolecules. In the right frame (132) of FIG. 16, the molecular structural formula during the condensation reaction 132 is only schematically presented.

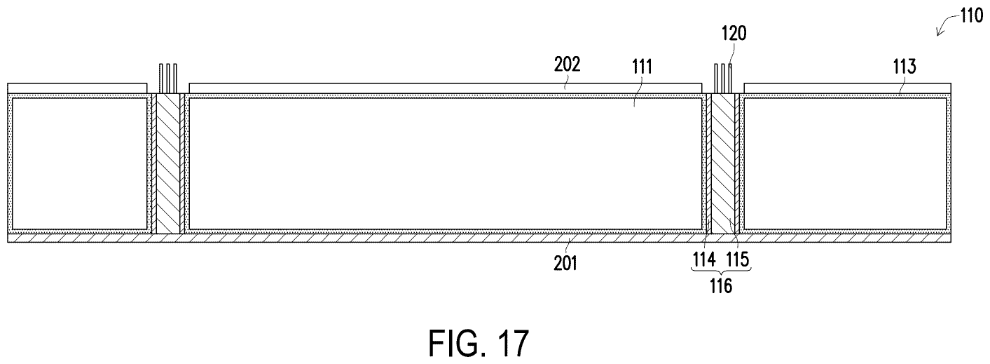

Referring to FIG. 17, a portion of the organic resin layer 202 may be removed by an appropriate method (e.g., etching or laser ablation) to expose the conductive via 116 for alignment.

Please continue to refer to FIG. 17, the conductive nano-wires 120 may be formed in the same or similar method as described above. The conductive nano-wires 120 may be formed directly on conductive vias 116.

In addition, after the conductive nano-wires 120 are formed, the fourth conductive layer 201 may be correspondingly removed in appropriate steps.

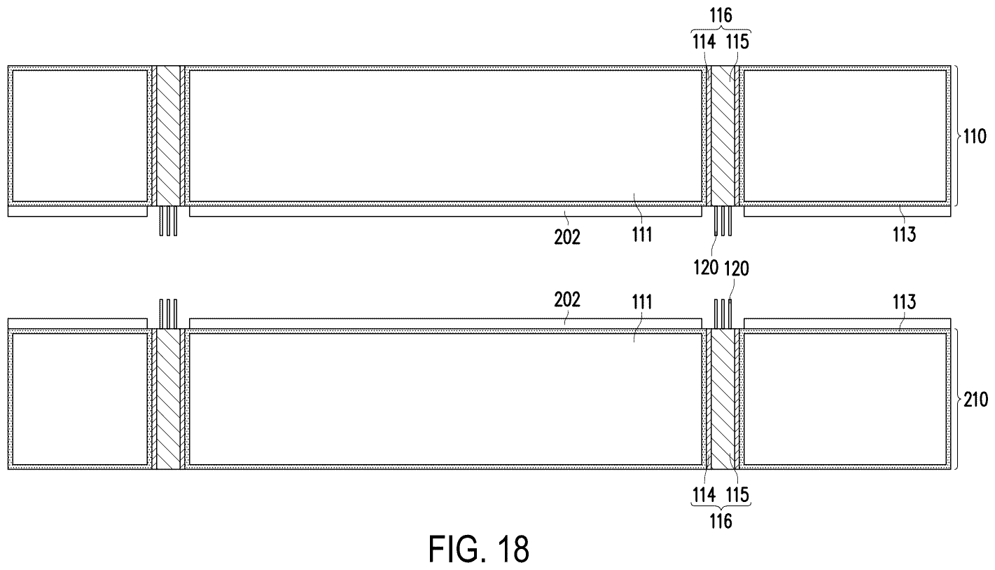

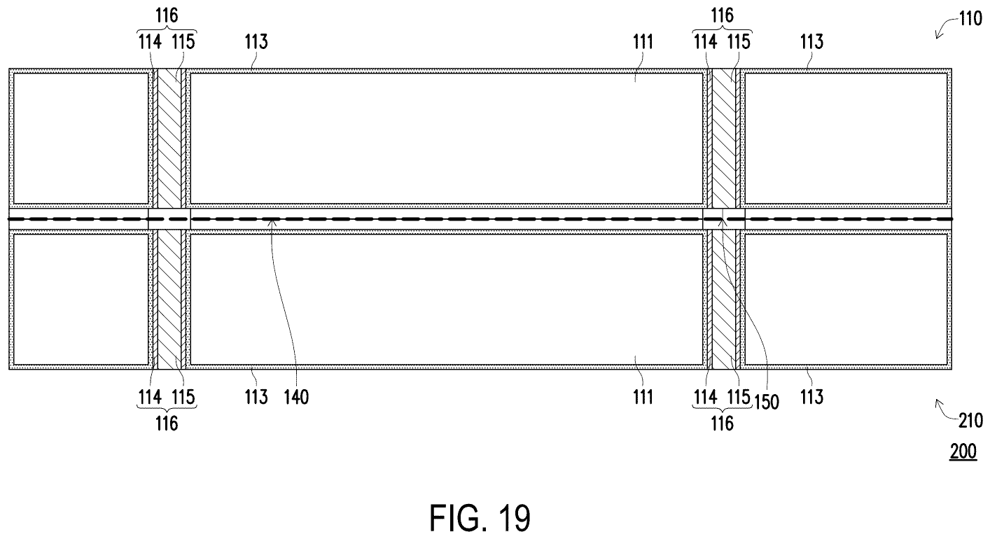

FIG. 18 to FIG. 19 are partial cross-sectional schematic diagrams of the bonding two substrates 110 and 210 to form the substrate structure 200 of the second embodiment of the disclosure.

Referring to FIG. 18, the first substrate 110 and the second substrate 210 are bonded during heating, so that the organic resin layer 202 on the core layer 111 of the first substrate 110 and the organic resin layer 202 on the core layer of the second substrate 210 are bonded through chemical bonding force (as described above). Furthermore, the conductive nano-wires 120 on the conductive via 116 of the first substrate 110 and the conductive nano-wires 120 on the conductive via 116 of the second substrate 210 are also heated to perform metal-to-metal diffusion bonding.

Therefore, the organic resin layer 202 and the conductive nano-wires 120 on the core layer 111 of the first substrate 110 are bonded to the organic resin layer 202 and the conductive nano-wires 120 on the core layer 111 of the second substrate 210 to form the substrate structure 200 of the second embodiment.

Please continue to refer to FIG. 19, the substrate structure 200 of the second embodiment of the disclosure includes a first substrate 110 and a second substrate 210. In one embodiment, both the first substrate 110 and the second substrate 210 include a core layer 111 and a conductive via 116. In one embodiment, an insulating layer 113 may be selectively included on the core layer 111 and on the sidewalls of the conductive via 116. The conductive via 116 may include a first conductive layer 114 and a second conductive layer 115. The organic resin layer 202 may be disposed on the core layer 111.

In the aforementioned embodiment, conductive nano-wires for alignment are formed on a conductor (e.g., conductive via 116). Moreover, conductors for alignment in different substrates (e.g., the first substrate 110 and the second substrate 210) may be bonded by the conductive nano-wires included therein. Moreover, insulators for alignment in different substrates (e.g., the first substrate 110 and the second substrate 210) may form a chain or network structure with bridging atoms (e.g., bridging oxygen) through covalent bonds, so that insulators for alignment in different substrates are bonded. Because the aforementioned two types of bonding (i.e., the bonding of conductors and insulators) may form an effective bond (e.g., atomic bridges may be formed; and, metal-to-metal diffusion bonding) at low heating temperatures (e.g., lower than the melting point of metallic copper) due to the materials and/or structures for alignment (e.g., materials with silicone and siloxane-based material; and, copper nano-wires), therefore, the possibility of thermal damage and/or thermal warping to the elements due to heating during the bonding process may be reduced. In this way, the quality and effect of the bonding may be improved.

In the aforementioned embodiments, the conductive layer may be a single layer or a multi-layer structure. If the conductive layer is a multi-layer structure, there may be no insulating material or dielectric material in between the multi-layer structure. In addition, in terms of structure, if it is a conductive layer of a multi-layer structure, even if the multi-layer structure is formed by different manufacturing processes, it may (but is not limited to) be represented by the same terms and/or reference numerals.

In the aforementioned embodiments, the insulating layer may be a single layer or a multi- layer structure. If it is an insulating layer with a multi-layer structure, there may be no conductive material in between the multi-layer structure. In addition, in terms of structure, if it is an insulating layer of a multi-layer structure, even if the multi-layer structure is formed by different manufacturing processes, it may (but is not limited to) be represented by the same terms and/or reference numerals.

In the aforementioned embodiments, one conductor and another conductor may be electrically connected to each other through the aligned conductive elements (e.g., conductive vias and wires). That is, unless otherwise stated or implied, even if one conductor and another conductor are not shown in the diagrams, the aforementioned one conductor and the aforementioned another conductor may still be electrically connected to each other through conductive elements that are not illustrated or not shown in cross-section in the diagrams.

What is claimed is:

1. A manufacturing method of a substrate structure, comprising:
providing a first substrate comprising a first core layer and a first conductor that is exposed;
providing a second substrate comprising a second core layer and a second conductor that is exposed;
forming conductive nano-wires on the first conductor or the second conductor; and
aligning the first conductor of the first substrate with the second conductor of the second substrate, and locating the conductive nano-wires between the first conductor and the second conductor, so that the first substrate and the second substrate are bonded by at least conductive diffusion bonding formed by the conductive nano-wires.

2. The manufacturing method of the substrate structure according to claim 1, wherein the first conductor or the second conductor comprises a same material as the conductive nano-wires.

3. The manufacturing method of the substrate structure according to claim 2, wherein the first conductor or the second conductor comprises a copper layer, and the conductive nano-wires are copper nano-wires.

4. The manufacturing method of the substrate structure according to claim 3, wherein the copper nano-wires are directly formed on the copper layer.

5. The manufacturing method of the substrate structure according to claim 1, wherein the first substrate or the second substrate further comprises a polymer, and during the aligning the first conductor of the first substrate with the second conductor of the second substrate, the polymer is further located between the first core layer and the second core layer, so that the first substrate and the second substrate are further bonded through a chain or network structure formed by the polymer.

6. The manufacturing method of the substrate structure according to claim 5, wherein during a process of bonding the first substrate and the second substrate that are separated from each other, a temperature is less than or equal to 200° C.

7. The manufacturing method of the substrate structure according to claim 6, wherein the polymer comprises a silicone polymer, and the chain or network structure has at least bridging oxygen.

8. A substrate structure, comprising:
a first substrate, comprising a first core layer and a first conductor; and
a second substrate, comprising a second core layer and a second conductor, wherein:
there is a metal diffusion bonding interface between the first conductor and the second conductor; and
there is a covalent bonding interface between the first core layer and the second core layer.

9. The substrate structure according to claim 8, wherein the metal diffusion bonding interface is a copper diffusion bonding interface.

10. The substrate structure according to claim 8, wherein the covalent bonding interface is a chain or network structure having at least bridging oxygen.
